(19) United States
(12) Patent Application Publication
(10) Pub. No.: US 2003/0227049 A1
(43) Pub. Date: Dec. 11, 2003

(54) Non-volatile semiconductor memory device

(75) Inventor: Kiyohiko Sakakibara, Hyogo (JP)

Correspondence Address: LEYDIG VOIT & MAYER, LTD, 700 THIRTEENTH ST. NW, SUITE 300, WASHINGTON, DC, 20005-3960, US

(73) Assignee: Mitsubishi Denki Kabushiki Kaisha, Tokyo (JP)

(21) Appl. No.: 10/281,325

(22) Filed: Oct. 28, 2002

(30) Foreign Application Priority Data
Jun. 11, 2002 (JP) 2002-169744

(51) Int. Cl. H01L 29/788

(52) U.S. Cl. 257/315

(57) ABSTRACT

A MONOS element includes: a first gate insulating film formed on a main surface so as to be located on an n-type well region; a first gate electrode provided on first gate insulating film; and a pair of p-type impurity regions and formed of p-type impurity regions. First insulating film includes: a first silicon oxide film; a silicon nitride film; and a second silicon oxide film formed on silicon nitride film. A field-effect transistor includes a second insulating film made of the same material as that of first insulating film.

### BACKGROUND OF THE INVENTION

1. Field of the Invention

The present invention relates to a non-volatile semiconductor memory device, and more particularly to a non-volatile semiconductor memory device capable of storing information by accumulating an electric charge in a gate insulating film.

2. Description of the Background Art

A MONOS Metal-Oxide-Nitride-Oxide Semiconductor) type non-volatile semiconductor memory device wherein a charge accumulation unit for accumulating an electric charge is formed from an insulating film are known as non-volatile semiconductor memory devices in addition to a floating gate-type non-volatile semiconductor memory device wherein a floating gate is formed for holding an electric charge.

Electrons are stored in a carrier trap in a silicon nitride film for holding an electric charge and in a carrier trap of an interface between the silicon nitride film and a silicon oxide film in the MONOS type non-volatile semiconductor memory device. Information can be stored according to the existence of these electrons.

The MONOS type non-volatile semiconductor memory device is, in general, constituted by an ONO (Oxide-Nitride-Oxide) film formed on a silicon substrate, a gate electrode formed on the ONO film, and source and drain regions formed in the semiconductor substrate across the gate electrode.

Such a MONOS type non-volatile semiconductor memory device is, for example, described in Japanese Patent Laying-Open No. 2001-230332.

A plurality of MONOS type non-volatile semiconductor memory elements generally constitutes a memory cell region in a non-volatile semiconductor memory device using MONOS type non-volatile semiconductor memory elements. The plurality of MONOS type non-volatile semiconductor memory elements is arranged in a matrix wherein the respective source regions are connected to each other.

Accordingly, in the case that one MONOS type non-volatile semiconductor memory element is selected, a voltage is applied to the source line of the element, and the voltage is also applied to the source line of other MONOS type non-volatile semiconductor memory elements that share the source line. Therefore, the other MONOS type non-volatile semiconductor memory elements that have not been intentionally selected are also selected. In order to prevent this, a technique for forming selection transistors for the respective MONOS type non-volatile semiconductor memory elements has been under development. However, in the case that field-effect transistors are connected to the respective MONOS type non-volatile semiconductor memory elements as selection transistors, a problem arises wherein the number of manufacturing steps is increased.

In addition, in the case that electrons are injected into an ONO film using GIDL (Gate Induced Drain Leakage), there is a demand for increased injection efficiency of electrons.

### SUMMARY OF THE INVENTION

The present invention is made in order to solve the above described problems, and one object of the present invention is to provide a non-volatile semiconductor memory device having a field-effect transistor capable of selecting a MONOS type non-volatile semiconductor memory element without increasing the number of manufacturing steps.

Another object of the present invention is to provide a non-volatile semiconductor memory device having MONOS type non-volatile semiconductor memory elements with high injection efficiency of electrons.

A non-volatile semiconductor memory device according to one aspect of the present invention is provided with: a semiconductor substrate having a main surface; an n-type semiconductor region formed in the semiconductor substrate; a non-volatile semiconductor memory element formed in the n-type semiconductor region; and a field-effect transistor formed in the n-type semiconductor region so as to be connected to the non-volatile semiconductor memory element. The non-volatile semiconductor memory element includes: a first gate insulating film formed on the main surface so as to be located on the n-type semiconductor region; a first gate electrode provided on the first gate insulating film; and a pair of source region and drain region formed in the n-type semiconductor region across the first gate electrode and constituted by a p-type impurity region. The first gate insulating film includes: a first silicon oxide film formed on the main surface; a silicon nitride film formed on the first silicon oxide film; and a second silicon oxide film formed on the silicon nitride film. The non-volatile semiconductor memory device stores information by injecting an electron into the first gate insulating film. The field-effect transistor is formed on the main surface so as to be located on the n-type semiconductor region, and includes a second gate insulating film made of the same material as that of the first gate insulating film.

In the non-volatile semiconductor memory device formed in such a manner, the field-effect transistor includes a second gate insulating film made of the same material as that of the first gate insulating film. Therefore, the first gate insulating film and the second gate insulating film can be manufactured in the same step so that the field-effect transistor can be formed as a selection transistor without increasing the number of manufacturing steps.

A non-volatile semiconductor memory device according to another aspect of the present invention is provided with: a semiconductor substrate having a main surface; an n-type semiconductor region formed in the semiconductor substrate; a non-volatile semiconductor memory element formed in the n-type semiconductor region; a p-type semiconductor region formed in the semiconductor substrate; and a field-effect transistor formed in the p-type semiconductor region. The non-volatile semiconductor memory element includes: a first gate insulating film formed on the main surface so as to be located on the n-type semiconductor region; a first gate electrode formed on the first gate insulating film; a first sidewall insulating film formed on a sidewall of the first gate electrode; and a pair of source region and drain region formed in the n-type semiconductor region across the first gate electrode and constituted by a p-type impurity region. The first gate insulating film includes a first silicon oxide film formed on the main surface; a silicon nitride film formed on the first silicon oxide film; and a second silicon oxide film formed on the silicon nitride film. The non-volatile semiconductor memory element stores information by injecting an electron into the first gate insulating film. The field-effect transistor includes: a second gate electrode formed on the p-type semiconductor region so as to interpose a second gate insulating film therebetween; and a second sidewall insulating film formed on a sidewall of the second gate electrode. The width of the first sidewall insulating film in the channel length direction is smaller than the width of the second sidewall insulating film in the channel length direction.

In the non-volatile semiconductor memory device formed in such a manner, the width of the first sidewall insulating film is smaller than the width of the second sidewall insulating film and, therefore, the source region and the drain region can be formed so that the width of a portion facing to the first gate electrode becomes great in the non-volatile semiconductor memory element in which the first sidewall insulating film is formed. As a result, it becomes easy to generate a hot electron in the portion of the drain region facing to the first gate electrode so that injection of an electron into the first gate insulating film becomes easy. Furthermore, the width of a second sidewall insulating film formed on a sidewall of the second gate electrode of the field-effect transistor, which is an n-channel type transistor, becomes relatively great and, therefore, the width of the source region or of the drain region formed beneath this sidewall insulating film becomes great. An n-channel type field-effect transistor has, in general, a problem that hot carriers easily generate. Therefore, the generation of hot carriers can be prevented by placing the source region and the drain region at a distance from each other in the n-channel type field-effect transistor.

A non-volatile semiconductor memory device according to still another aspect of the present invention is provided with: a semiconductor substrate having a main surface; an n-type semiconductor region formed in the semiconductor substrate; and a non-volatile semiconductor memory element formed in the n-type semiconductor region. The non-volatile semiconductor memory element includes: a first gate insulating film formed on the main surface so as to be located on the n-type semiconductor region; a first gate electrode provided on the first gate insulating film; and a pair of source region and drain region formed in the n-type semiconductor region across the first gate electrode and constituted by a p-type impurity region. The first gate insulating film includes: a first silicon oxide film formed on the main surface; a silicon nitride film formed on the first silicon oxide film; and a second silicon oxide film formed on the silicon nitride film. The non-volatile semiconductor memory element stores information by injecting an electron into the first gate insulating film. The source region and the drain region have portions making contact with the first silicon oxide film and facing to the first gate electrode. The width of the portion of the drain region facing to the first gate electrode is greater than the width of the portion of the source region facing to the first gate electrode.

In the non-volatile semiconductor memory device formed in such a manner, the width of the portion of the drain region facing to the first gate electrode is greater than the width of the portion of the source region facing to the first gate electrode and, therefore, a hot electron is generated in the portion of the drain region facing to the first gate electrode so that it becomes possible to inject the electron into the first gate insulating film. As a result, it becomes easy to inject an electron from the drain region.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1A is a plan view showing a non-volatile semiconductor memory device according to a first embodiment of the present invention;

FIG. 1B is an equivalent circuit diagram showing the non-volatile semiconductor memory device according to the first embodiment of the present invention;

FIG. 2 is a cross sectional view taken along a line II-II in FIG. 1A;

FIGS. 3 to 15 are cross sectional views showing first to thirteen steps of a manufacturing method for the non-volatile semiconductor memory device shown in FIG. 2;

FIG. 16 is a cross sectional view showing a non-volatile semiconductor memory device according to a second embodiment of the present invention;

FIG. 17 is a cross sectional view showing a non-volatile semiconductor memory device according to a third embodiment of the present invention;

FIG. 18 is a cross sectional view showing a non-volatile semiconductor memory device according to a fourth embodiment of the present invention;

FIG. 19 is a cross sectional view showing a non-volatile semiconductor memory device according to a fifth embodiment of the present invention; and

FIG. 20 is a cross sectional view showing a manufacturing step of the non-volatile semiconductor memory device shown in FIG. 19.

### DESCRIPTION OF THE PREFERRED EMBODIMENTS

Hereinafter, embodiments of the present invention will be described with reference to the drawings.

First Embodiment

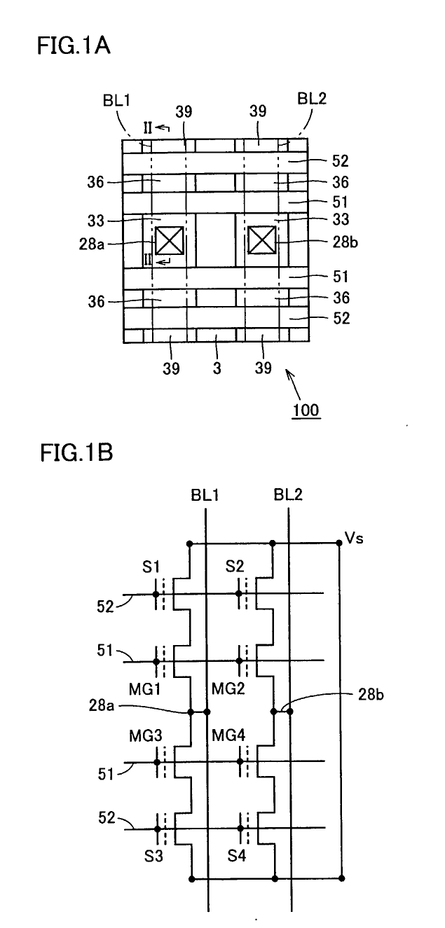

With reference to FIGS. 1A and 1B, an isolation insulating film 3 is formed on a semiconductor substrate made of a silicon substrate in a non-volatile semiconductor memory device 100 according to a first embodiment of the present invention. A portion where isolation insulating film 3 is not formed is an active region, and p-type impurity regions 33, 36 and 39 which constitute source and drain regions are formed in this portion. A plurality of first and second gate electrodes 51 and 52 is formed in the direction orthogonal to the direction in which isolation insulating film 3 extends, and p-type impurity regions 33, 36 and 39, respectively, are formed between these first and second gate electrodes 51 and 52. Contact holes 28a and 28b are provided so as to reach p-type impurity regions 33. Contact holes 28a and 28b allow p-type impurity regions 33 to be connected to bit lines BL1 and BL2 provided on first and second gate electrodes 51 and 52.

Memory cell transistors MG1 to MG4 and selection transistors S1 to S4 are connected to each other and these share gate insulating films. Memory cell transistors MG1 and MG2 share a first gate electrode 51. Memory cell transistors MG3 and MG4 share a first gate electrode 51. Selection transistors S1 and S2 share a second gate electrode 52. Selection transistors S3 and S4 share a second gate electrode 52.

Memory cell transistors MG1 and MG3 are connected to bit line BL1 while memory cell transistors MG2 and MG4 are connected to bit line BL2.

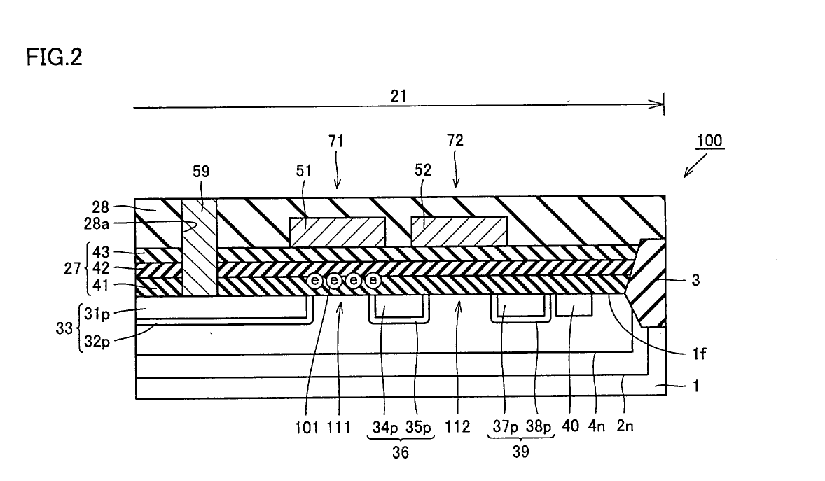

With reference to FIG. 2, a non-volatile semiconductor memory device 100 is provided with: a semiconductor substrate 1 having a main surface 1f; an n-type well region 2n as an n-type semiconductor region formed in semiconductor substrate 1; a MONOS element 71 as a non-volatile semiconductor memory element formed in n-type well region 2n; and a field-effect transistor 72 formed in n-type well region 2n so as to be connected to MONOS element 71.

MONOS element 71 includes: a first gate insulating film 111 formed on main surface 1f so as to be located on n-type well region 2n; a first gate electrode 51 provided on first gate insulating film 11; and a pair of p-type impurity region 33 as a source region and p-type impurity region 36 as a drain region formed on n-type well region 2n across first gate electrode 51. First gate insulating film 1 includes: a first silicon oxide film 41 formed on main surface 1f; a silicon nitride film 42 formed on first silicon oxide film 41; and a second silicon oxide film 43 formed on silicon nitride film 42. MONOS element 71 stores information by injecting an electron 101 into first gate electrode 51. The electron is injected into any of first silicon oxide film 41, silicon nitride film 42 and second silicon oxide film 43 or into interfaces between these films and are held therein. That is to say, the electron is injected into first gate insulating film 111 and are held therein. Thereby, information is stored.

Field-effect transistor 72 is formed on main surface 1f so as to be located on n-type well region 2n and includes a second gate insulating film 112 made of the same material as that of first gate insulating film 111.

P-type impurity region 33, as a drain region, has a portion making contact with first silicon oxide film 41 and facing to first gate electrode 51. A hot electron is generated in the portion of p-type impurity region 33, as a drain region, facing to first gate electrode 51 and electron 101 is injected into silicon nitride film 42. First gate insulating film 111 and second gate insulating film 112 make direct contact with each other.

According to this embodiment, MONOS element 71 and field-effect transistor 72 are formed in one cell. Therefore, in the case that MONOS element 71 is not selected, field-effect transistor 72 is turned off. As a result, a so-called channel cutoff potential applied to the unselected MONOS elements becomes unnecessary. Two transistors are formed in one memory cell region and, therefore, the area per bit increases. Therefore, it is necessary to reduce, as much as possible, the size of these two transistor structures. In order to achieve this, second gate insulating film 112 of field-effect transistor 72, which is a selection transistor, is also given an ONO structure, so that excessive mask adjustments are made unnecessary, as shown in FIG. 2.

Isolation insulating film 3 is formed in the surface of semiconductor substrate 1 formed from a silicon substrate. Isolation insulating film 3 may be formed either by LOCOS (local oxidation) or by trench isolation. N-type well region 2n is formed in semiconductor substrate 1. A counter-doped region 4n wherein n-type impurities are included is formed within n-type well region 2n. A plurality of p-type impurity regions 33, 36 and 39 is formed within counter-doped region 4n. In addition, an n-type impurity region 40 is also formed.

P-type impurity regions 33, 36 and 39, respectively, are constituted by p-type impurity regions 31p, 34p and 37p of a high concentration, of which the p-type impurity concentration is relatively high, and of p-type impurity regions 32p, 35p and 38p of a low concentration, of which the p-type impurity concentration is relatively low.

An ONO (oxide-nitride-oxide) film 27 made by layering a first silicon oxide film 41, a silicon nitride film 42 and a second silicon oxide film 43 is formed on main surface 1f.

First gate insulating film 111 and second gate insulating film 112, respectively, are constituted by ONO film 27. First gate electrode 51 of MONOS element 71 and second gate electrode 52 of field-effect transistor 72 are formed on ONO film 27. First gate electrode 51 is formed between p-type impurity regions 33 and 36 while second gate electrode 52 is formed between p-type impurity regions 36 and 39.

An interlayer insulating film 28 is formed so as to cover ONO film 27 as well as first and second gate electrodes 51 and 52. A contact hole 28a is formed in interlayer insulating film 28 so as to reach p-type impurity region 33 and a plug layer 59 as a drain contact plug is filled into contact hole 28a. Noted that MONOS element 71 and field-effect transistor 72 are both formed within a memory cell region 21.

Noted that one of the reasons why field-effect transistor 72, as a selection transistor, is formed on the p-type impurity region 36 side, which is the source region of MONOS element 71, is that the bit line potential at the time of write-in of data to MONOS element 71 is prevented from becoming lower via field-effect transistor 72.

Furthermore, in this embodiment, electron 101 is injected into silicon nitride film 42 within first gate insulating film 111 by means of GIDL. That is to say, a high electrical field is formed in a region (region overlapping first gate electrode 51) facing to first gate electrode 51 of p-type impurity region 31p of a high concentration in p-type impurity region 33 as a drain region. As a result of this, tunneling of electrons from a valence band to a conduction band is caused, thereby electron-hole pairs are formed causing a leak current. As a result, electrons are injected into silicon nitride film 42.

The voltages for the operation in this MONOS element 71 are, for example, as follows. First, at the time of write-in, the potential Vd of p-type impurity region 33, as a drain region, is −5 V, the potential Vg of first gate electrode 51 is 5 V, the potential of p-type impurity region 36, which is a source region, is 0 V or is open, and the potential Vnwell of n-type well region 2n is 0V.

At the time of erasure, the potential Vd of p-type impurity region 33, as a drain region, is open, the potential Vg of first gate electrode 51 is −7 V, the potential Vs of p-type impurity region 36, which is a source region, is open or is 7 V, and the potential Vnwell of n-type well region 2n is 7 V.

At the time of read-out, the potential Vd of p-type impurity region 33, as a drain region, is −2.5 V, the potential Vg of first gate electrode 51 is −2.5 V, the potential Vs of p-type impurity region 36, which is a source region, is 0 V, and the potential Vnwell of n-type well region 2n is 0 V. Noted that these potentials are attained in the case that the threshold voltage Vth of a long channel transistor is assumed as being set at approximately Vth >3 V when no electrons are stored in ONO film 27.

Here, the use of a GIDL-induced hot electron injection by forming a cell of p-channel transistors has already been reported, including by the present inventor, as a method of injection of electrons into a floating gate electrode. Concretely, it is described in IEDM Tech. Dig., 1995, p. 279, “Novel Electron Injection Method Using Band-to-Band Tunneling Induced Hot Electron for Flash Memory with a P-channel Cell.” The above described injection method is used in a non-volatile semiconductor memory device that has been structurally simplified, leading to a lowering of cost, by replacing, as an electron storage portion, the floating gate according to the concept in the above described reference with an ONO interface trap. In the case that this method of injection of electrons is used, electron injection can be carried out in a low electrical field. Since electrons are not trapped in an oxide film, the property of withstanding against rewriting is enhanced.

Here, it is necessary to withdraw electrons from the silicon nitride film at the time of data erasure. According to this method, the channel FN tunnel phenomenon is used. Thereby, deterioration of first silicon oxide film 41 can be restricted. In addition, it is preferable for the withdrawal of electrons to be carried out as a unit in the array block, in the same manner as in flash memory. In this case, well division per bit is not necessary so that an increase in the area of the memory block and of the decoder can be restricted.

In order to increase the GIDL efficiency, it is necessary for a portion where first gate electrode 51 and p-type impurity region 33, having p-type impurity region 31p of a high concentration wherein the concentration of p-type impurities is 10¹⁹ cm⁻³ or greater, face each other, to exist. Therefore, in order to increase the GIDL efficiency in MONOS element 71, a conversion to a thin film for a sidewall on only the side wherein the GIDL-induced electron injection is made to generate or a conversion of a high concentration of the p -type diffusion layer may become necessary.

On the other hand, in order to reduce the cell size in a configuration wherein two transistors are formed in one memory cell, it is necessary to form a portion without a gate between the cell transistor and the selection transistor, that is to say, a portion between the cell transistor and the selection transistor, of the minimum possible dimensions.

A p-type diffusion layer of a high concentration is, in general, formed through ion implantation after the formation of sidewalls. Thereby, the same steps as above can be used for manufacture of peripheral transistors, leading to a lowering of cost. Even in the case that the step of implanting p-type impurities of a high concentration is additionally carried out, after the formation of a sidewall on a space having the minimum dimensions as a result of patterning, it becomes difficult to effectively enhance the concentration of the p-type impurities. This is because, in some cases, the sidewall fills in the space between the gate electrode of the cell transistor and the gate electrode of the selection transistor. Therefore, the selection transistor is not provided on the drain side.

In the case that ONO film 27 of field-effect transistor 72, as a selection transistor, is removed in the same steps for processing peripheral transistors, it must be determined whether or not ONO is to be removed at the gate division portion between the cell transistor and the selection transistor. It is difficult to adjust the position of the mask for removing the ONO film in a region for removal having the minimum gate dimensions. Accordingly, the gate structure of field-effect transistor 72, that is a selection transistor, is formed of ONO film 27, thereby it becomes unnecessary to take into consideration the adjustment of the position of the mask. Furthermore, in the case that the selection transistor is provided on the source side, it is not necessary to be concerned about the potential drop, as described above, even when the oxide film thickness of the gate oxide film, having an ONO structure, effectively increases and the channel conductance is lowered.

Next, a manufacturing method for the non-volatile semiconductor memory device shown in FIG. 2 will be described.

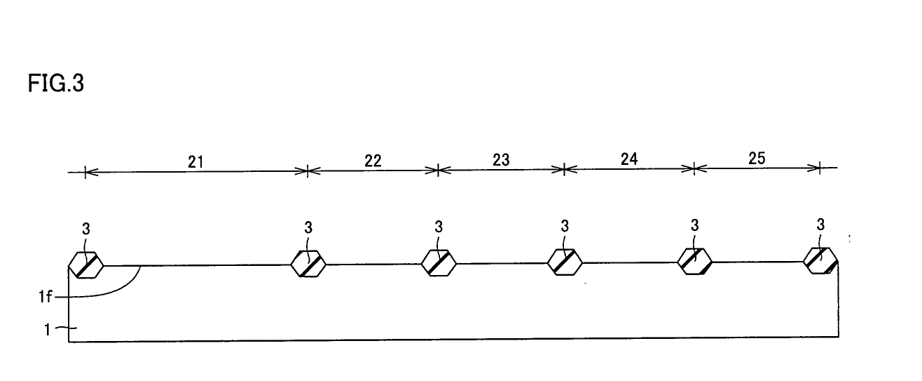

With reference to FIG. 3, a semiconductor substrate 1 made of a silicon substrate is prepared. A memory cell region 21, n-channel type transistor regions 22 and 23 as well as p-channel type transistor regions 24 and 25 are formed in semiconductor substrate 1. LOCOS or STI (shallow trench isolation) is formed in a main surface 1f of semiconductor substrate 1 as an element isolation structure.

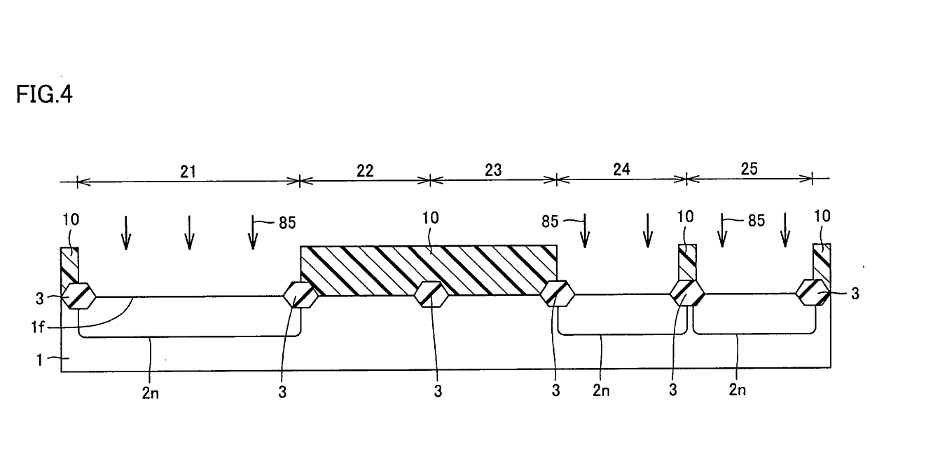

With reference to FIG. 4, a resist pattern 10 is formed on main surface 1f N-type impurity ions are injected into semiconductor substrate 1 in the direction shown by arrow 85 using resist pattern 10 as a mask, thereby n-type well regions 2n are formed. Noted that a logic circuit is formed in p-channel type transistor region 24 while a transistor driven at a high voltage is formed in p-channel type transistor region 25.

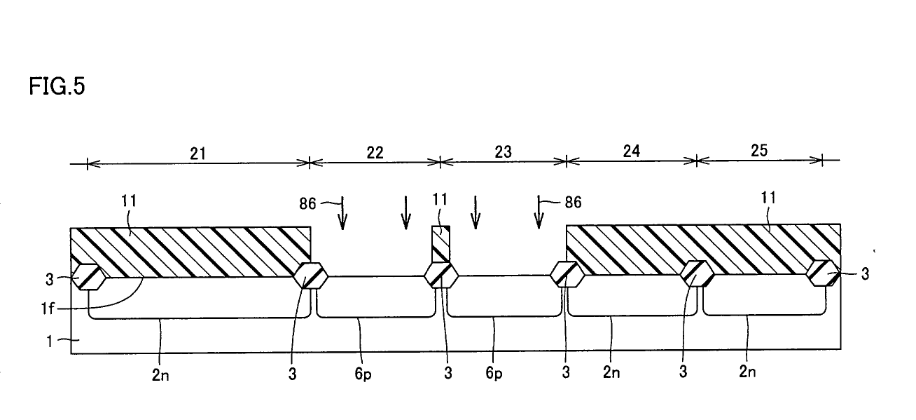

With reference to FIG. 5, a resist pattern 11 is formed on main surface 1f of semiconductor substrate 1. P-type impurity ions are injected into semiconductor substrate 1 in the direction shown by arrow 86 using resist pattern 11 as a mask. Thereby, p-type well regions 6p are formed. Here, a logic circuit is formed in n-channel type transistor region 22 while a high voltage driven transistor is formed in n-channel type transistor region 23.

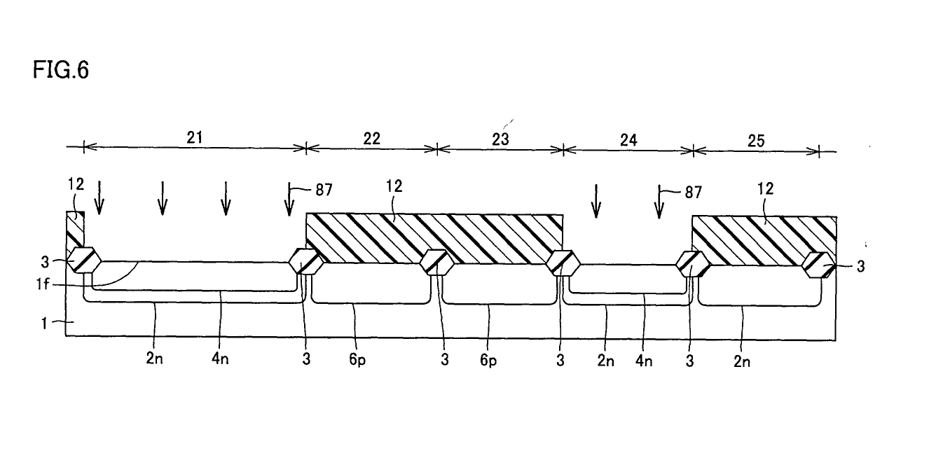

With reference to FIG. 6, a resist pattern 12 is formed on main surface 1f of semiconductor substrate 1. N-type impurity ions are injected into semiconductor substrate 1 in the direction shown by arrow 87 using resist pattern 12 as a mask. Thereby, counter-doped regions 4n are formed. Counter-doped regions 4n are formed in memory cell region 21 and in p-channel type transistor region 24. At this time, counter-doped regions 4n in memory cell region 21 and counter-doped region 4n in p-channel type transistor region 24 can be formed in the same injection step and, therefore, a reduction in the number of mask adjustments can be achieved, leading to a further lowering of cost.

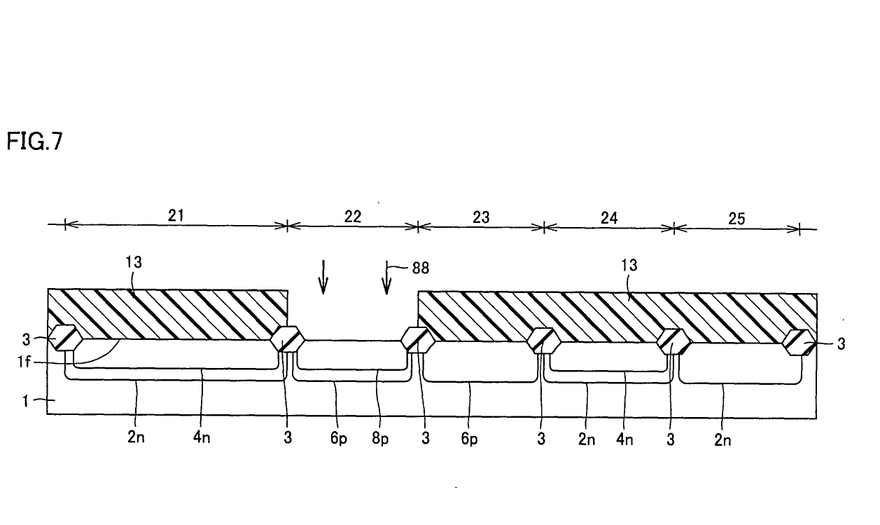

With reference to FIG. 7, a resist pattern 13 is formed so as to expose n-channel type transistor region 22 in the peripheral region. P-type impurity ions are implanted into semiconductor substrate 1 in the direction shown by arrow 88 using resist pattern 13 as a mask. Thereby, a counter-doped region 8p is formed within p-type well region 6p. Counter-doped region 8p is formed in n-channel type transistor region 22.

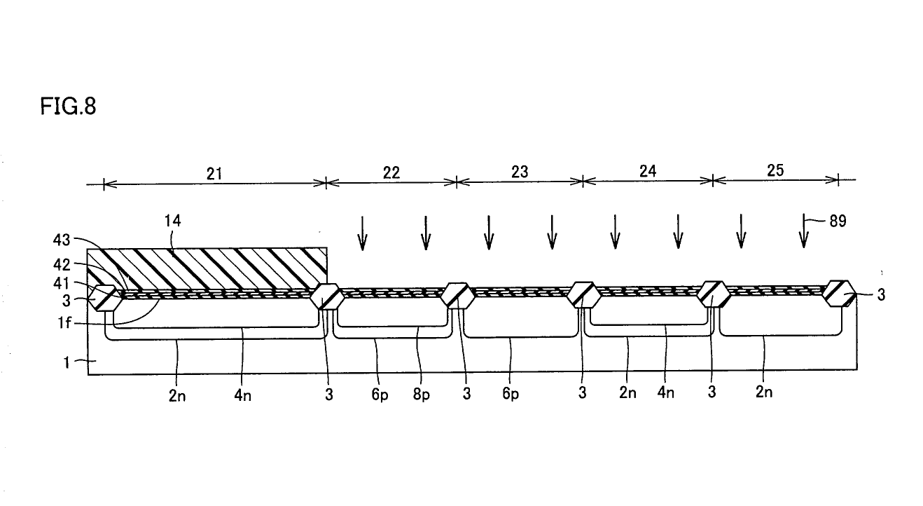

In reference FIG. 8, main surface 1f of semiconductor substrate 1 is oxidized, thereby a first silicon oxide film 41 is formed as a bottom oxide film. After that, a silicon nitride film 42 is formed by means of a CVD method (chemical vapor deposition method). A second silicon oxide film 43 is formed on silicon nitride film 42 as a top oxide film using TEOS (Tetra Ethyl Ortho Silicate) as a material. After that, a resist pattern 14 is formed for solely covering memory cell region 21. After that, an etchant is sprayed onto first silicon oxide film 41, silicon nitride film 42 and second silicon oxide film 43 in the direction shown by arrow 89, thereby the ONO film in the peripheral region is removed.

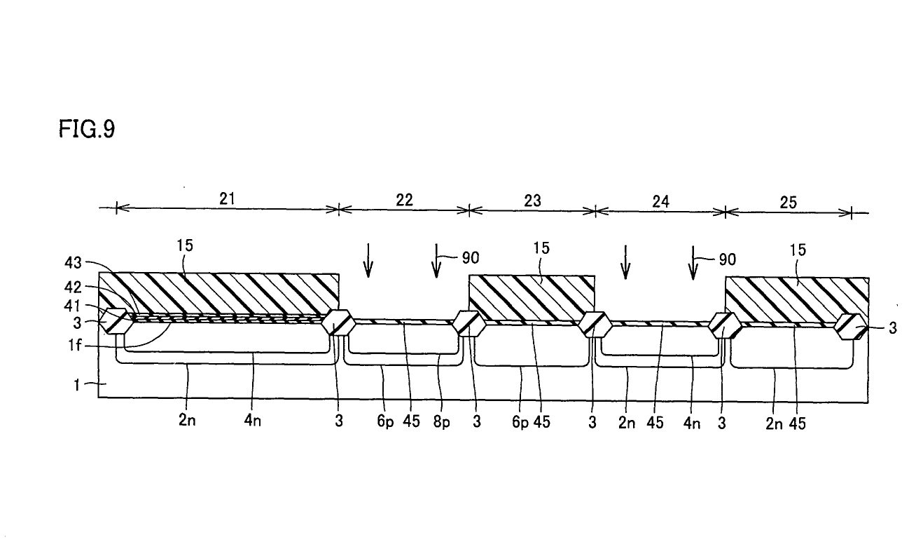

With reference to FIG. 9, thick gate insulating films 45 are formed in n-channel type transistor region 23, which has a peripheral high voltage system, and in p-channel type transistor region 24. In general, a high voltage system handles a high voltage in comparison with a logic system and, therefore, an oxide film of a great film thickness is used in a high voltage system. Such an oxide film is formed by carrying out two oxidation processes.

First, the first oxidation is carried out by taking the increase in the amount of oxidation of the gate in the logic system region in the post-process into consideration. After that, resist pattern 15 is formed through a photomechanical process. An etchant is sprayed onto gate insulating films 45 in n-channel type transistor region 22 and in p-channel type transistor region 24 in the direction shown by arrow 90, thereby gate insulating films 45 in these portions are removed.

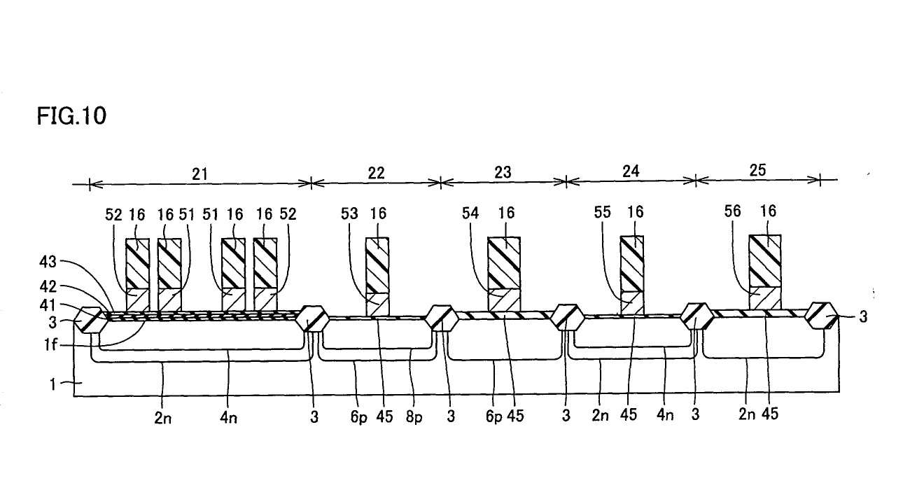

With reference to FIG. 10, gate oxidation is carried out on n-channel type transistor regions 22 and 23 as well as on p-channel type transistor region 24 and 25. As a result, gate insulating films 45 having the desired thicknesses are formed over the entirety of the peripheral region. A conductive material that becomes the gate electrodes is deposited. A resist pattern 16 is formed on this conductive material. The conductive material is etched using the resist pattern as a mask, thereby first and second gate electrodes 51 and 52, as well as gate electrodes 53 to 56 in the peripheral region, are formed.

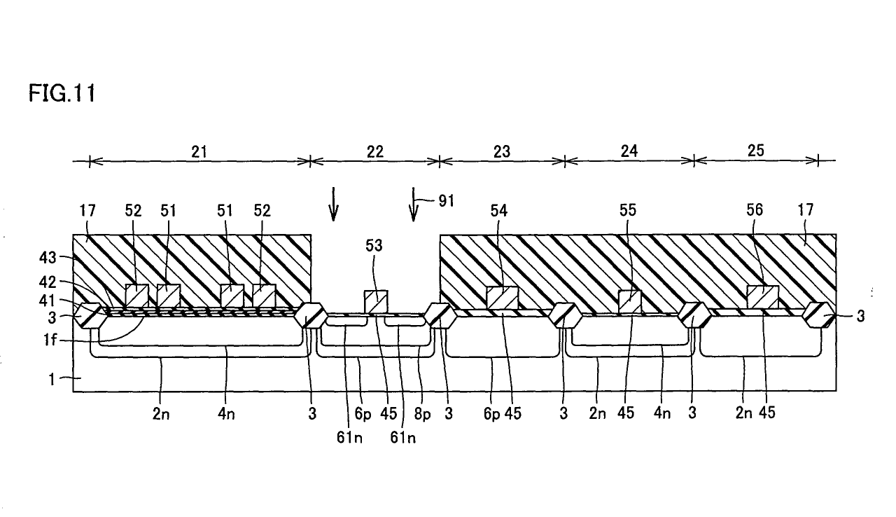

With reference to FIG. 11, a resist pattern 17 is formed on semiconductor substrate 1. Resist pattern 17 exposes n-channel type transistor region 22. N-type impurity ions are injected into n-channel type transistor region 22 in the direction shown by arrow 91, thereby n-type impurity regions 61n of a low concentration are formed on each side of gate electrode 53.

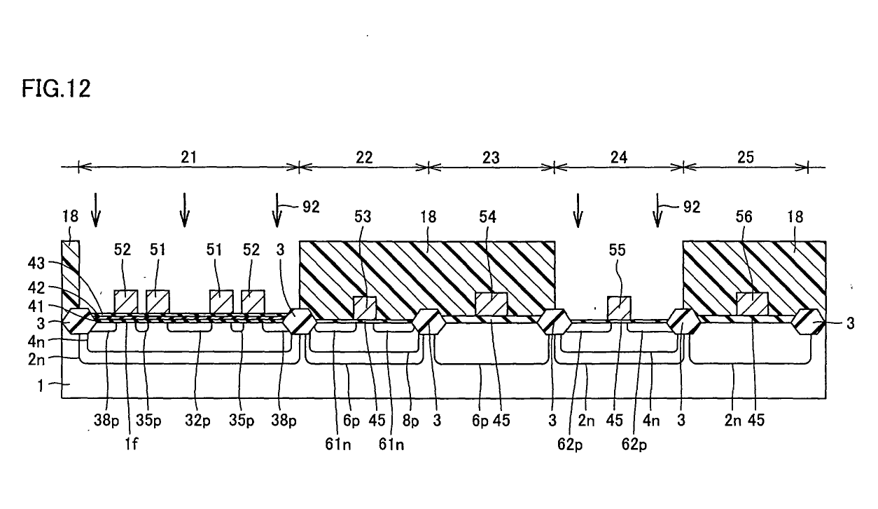

With reference to FIG. 12, a resist pattern 18 is formed on semiconductor substrate 1. Resist pattern 18 exposes memory cell region 21 and p-channel type transistor region 24. P-type impurity ions are injected into memory cell region 21 and p-channel type transistor region 24 in the direction shown by arrow 92 using resist pattern 18 as a mask. Thereby, p-type impurity regions 32p, 35p, 38p and 62p of a low concentration are formed.

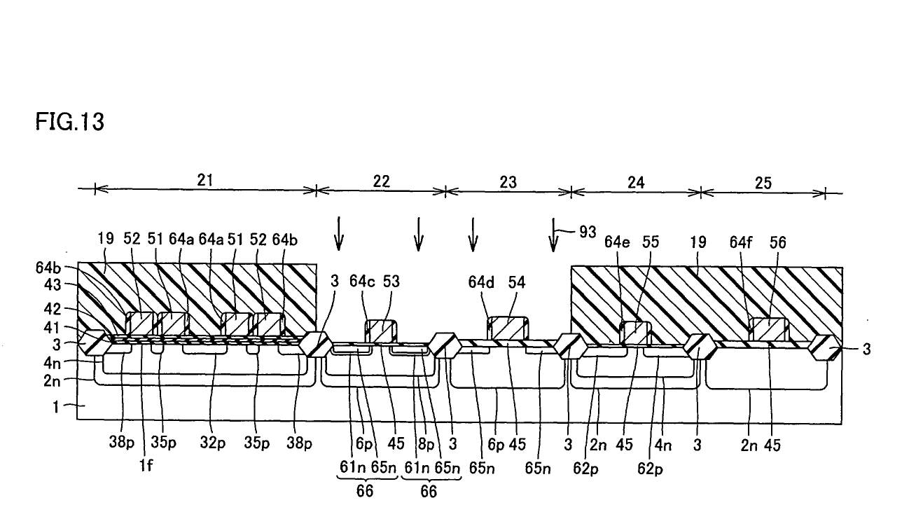

With reference to FIG. 13, a silicon oxide film is formed so as to cover first and second gate electrodes 51 and 52 as well as gate electrodes 53 to 56 and first sidewall insulating film 64a, second sidewall insulating film 64b and sidewall insulating films 64c to 64f are formed by etching back the entire surface of this silicon oxide film. A resist pattern 19 is formed on semiconductor substrate 1. Resist pattern 19 exposes n-channel type transistor regions 22 and 23. N-type impurity ions are injected into semiconductor substrate 1 in the direction shown by arrow 93 using resist pattern 19 as a mask. Thereby, n-type impurity regions 65n of a high concentration are formed.

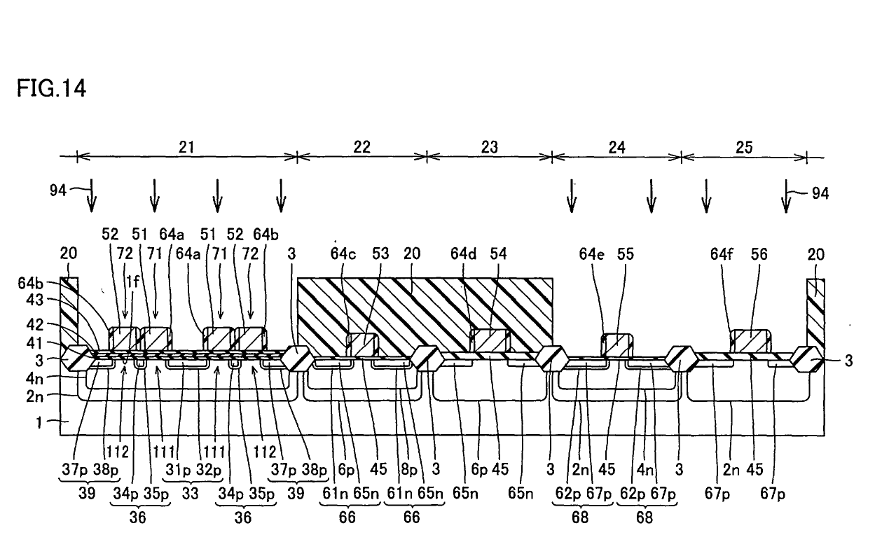

With reference to FIG. 14 a resist pattern 20 is formed on semiconductor substrate 1. Resist pattern 20 exposes memory cell region 21 as well as p-channel type transistor regions 24 and 25. P-type impurity ions are injected into memory cell region 21 as well as p-channel type transistor regions 24 and 25 in the direction shown by arrow 94 using resist pattern 20 as a mask. Thereby, p-type impurity regions 31p, 34p, 37p and 67p of a high concentration are formed.

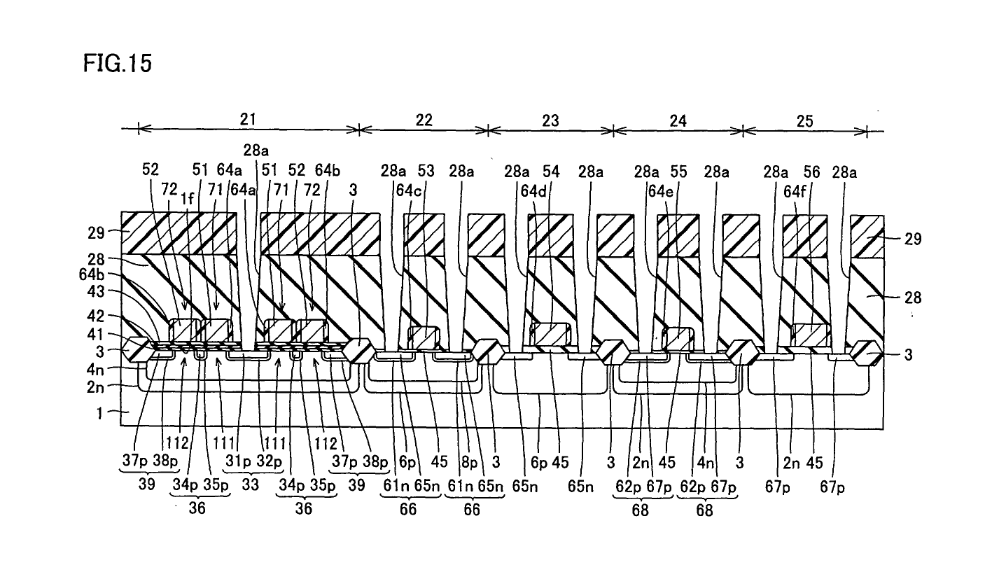

With reference to FIG. 15, an interlayer insulating film 28 is formed on semiconductor substrate 1. A resist pattern 29 having a predetermined pattern is formed on interlayer insulating film 28. Interlayer insulating film 28 is etched using resist pattern 29 as a mask, thereby contact holes 28a are formed. After that, plug layers are formed so as to fill in into contact holes 28a, and then a non-volatile semiconductor memory device shown in FIG. 2 is completed. Here, non-volatile semiconductor memory device 100 in FIG. 2 is shown as an enlarged view of a portion of memory cell region 21 in FIGS. 2 to 15.

In such a non-volatile semiconductor memory device, first gate insulating film 111 of MONOS element 71 and second gate insulating film 112 of field-effect transistor 72, which is a selection transistor, are formed of the same ONO film 27. Therefore, these ONO films 27 can be manufactured in one step so that field-effect transistor 72, which is a selection transistor, can be formed without increasing the number of manufacturing steps.

Second Embodiment

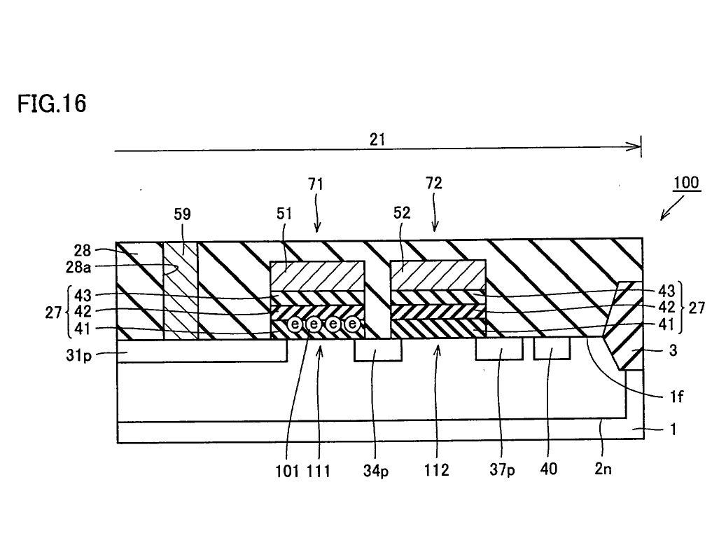

With reference to FIG. 16, a non-volatile semiconductor memory device 100 according to a second embodiment of the present invention differs from non-volatile semiconductor memory device 100 according to the first embodiment in the point that first gate insulating film 111 of MONOS element 71 and second gate insulating film 112 of field-effect transistor 72, which is a selection transistor, are separated from each other though they are formed of the same ONO film 27 in non-volatile semiconductor memory device 100 according to the second embodiment. Furthermore, the drain region of MONOS element 71 is formed solely of p-type impurity region 31p of a high concentration while the source region of MONOS element 71 is formed solely of p-type impurity region 34p of a high concentration. In addition, the source region of field-effect transistor 72 is formed solely of p-type impurity region 37p of a high concentration. Furthermore, a counter-doped region is not formed within n-type well region 2n.

Non-volatile semiconductor memory device 100 according to the second embodiment of the present invention, formed in the above described manner, has the same effects as of non-volatile semiconductor memory device 100 according to the first embodiment.

Third Embodiment

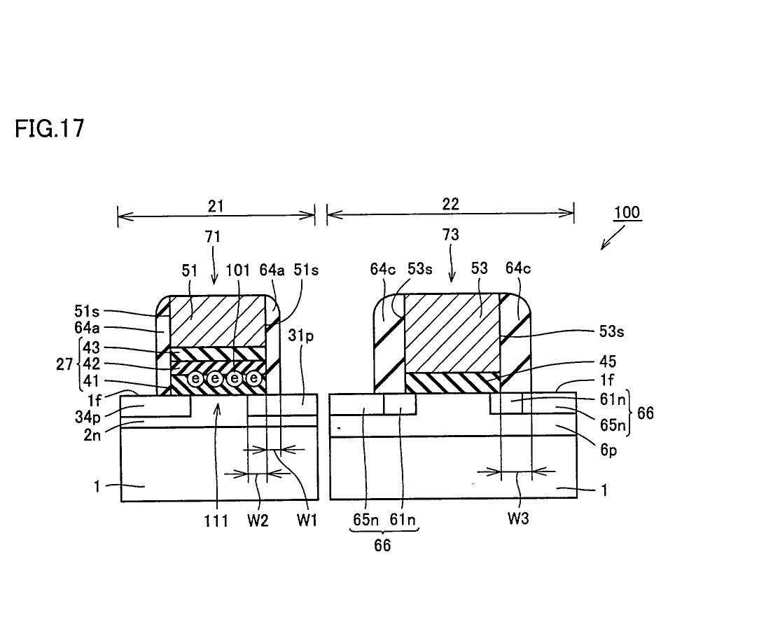

With reference to FIG. 17, a non-volatile semiconductor memory device according to a third embodiment of the present invention includes a memory cell region 21 and an n-channel type transistor region 22 of the first embodiment. N-type well region 2n is formed in semiconductor substrate 1 in memory cell region 21. P-type impurity region 34p of a high concentration as a source region and a p-type impurity region 31p of a high concentration as a drain region are formed in n-type well region 2n. A first gate insulating film 111 is formed between p-type impurity regions 31p and 34p of a high concentration. First gate insulating film 111 is constituted by an ONO film 27. ONO film 27 is constituted by a first silicon oxide film 41, a silicon nitride film 42 formed on first silicon oxide film 41 and a second silicon oxide film 43 formed on silicon nitride film 42. A first gate electrode 51 is formed on first gate insulating film 111. Sidewall insulating films 64a are formed on sidewalls 51s of first gate electrode 51.

P-type well region 6p is formed in semiconductor substrate 1 in n-channel type transistor region 22. A pair of n-type impurity regions 66 is formed in p-type well region 6p. N-type impurity regions 66 are constituted by n-type impurity regions 61n of a low concentration, wherein the n-type impurity concentration is low, and of n-type impurity regions 65n of a high concentration, wherein the n-type impurity concentration is high.

A gate insulating film 45 constituted by a silicon oxide film is formed between the pair of n-type impurity regions 66. A gate electrode 53 is formed on gate insulating film 45. Gate electrode 53 has sidewalls 53s, and sidewall insulating films 64c are formed so as to make contact with these sidewalls 53s.

Non-volatile semiconductor memory device 100 is provided with: semiconductor substrate 1 having main surface 1f; n-type well region 2n, as an n-type semiconductor region, formed in semiconductor substrate 1; MONOS element 71, as a non-volatile semiconductor memory element, formed in n-type well region 2n; p-type well region 6p, as a p-type semiconductor region, formed in semiconductor substrate 1; and field-effect transistor 73 formed in p-type well region 6p.

MONOS element 71 includes: first gate insulating film 111 formed on main surface 1f so as to be located on n-type well region 2n; first gate electrode 51 formed on first gate insulating film 111; first sidewall insulating films 64a formed on sidewalls 5 is of first gate electrode 51; pair of p-type impurity regions 34p and 31p of a high concentration, as a source region and a drain region, formed of p-type impurity regions on each side of first gate electrode 51 in n-type well region 2n.

First gate insulating film 111 includes: first silicon oxide film 41 formed on main surface 1f silicon nitride film 42 formed on first silicon oxide film 41; and second silicon oxide film 43 formed on silicon nitride film 42. MONOS element 71 stores information by injecting electrons 101 into silicon nitride film 42.

P-type impurity region 31p of a high concentration, as a drain region, has a portion making contact with first silicon oxide film 41 and facing to first gate electrode 51. Hot electrons are generated by means of GIDL in the portion of p-type impurity region 33, as a drain region, facing to first gate electrode 51 so that electrons 101 are injected into silicon nitride film 42.

Field-effect transistor 73 includes: second gate electrode 53 formed on p-type well region 6p so as to interpose gate insulating film 45 therebetween; and second sidewall insulating films 64c formed on sidewalls 53s of second gate electrode 53. The width W1 of first sidewall insulating films 64a is smaller than the width W3 of second sidewall insulating films 64c.

Field-effect transistor 73 includes a pair of n-type impurity regions 65n of a high concentration, as a source region and a drain region, constituted by n-type impurity regions on each side of gate electrode 53, as the second gate electrode, in p-type well region 6p. P-type impurity regions 31p and 34p of a high concentration as well as n-type impurity region 63n of a high concentration of MONOS element 71 and of field-effect transistor 73 are formed by injecting impurities into semiconductor substrate 1 using first and second sidewall insulating films 64a and 64c as a mask. Therefore, p-type impurity region 31p of a high concentration is formed up to the vicinity of first gate electrode 51.

In order to make GIDL efficiency generate as described above, p-type impurity regions 31p of a high concentration must be formed in the above described manner with respect to the gate electrode so that the impurity concentration thereof becomes of 10¹⁹ cm⁻³ or greater and p-type impurity region 31p of a high concentration overlaps gate electrode 51.

An additional new mask is not necessary for the formation of p-type impurity regions 31p and 34p of a high concentration, which is carried out in the same steps as for the formation of the source and drain regions of the transistors in the peripheral region. P-type impurity regions 31p and 34p of a high concentration are formed by implantation using sidewall insulating films 64a as a mask. Afterward, P-type impurity regions 31p and 34p of a high concentration spread through a thermal treatment so as to form gate overlap regions.

The main factors that decide the width of the sidewall insulating films are hot carrier effects within n-channel type transistor region 22 of a logic circuit. Accordingly, in the case that the width of each of first sidewall insulating films 64a is narrowed before the injection for p-type impurity regions 31p and 34p of a high concentration, it becomes easy to secure the overlap regions between first gate electrode 51 and p-type impurity region 31p of a high concentration, which are formed through a subsequent heat treatment.

The width of first sidewall insulating film 64a may be narrowed immediately before the step shown in FIG. 14 in the above described manufacturing method. In this case, n-type impurity regions 65n of a high concentration are formed according to the steps shown in FIG. 13 under the condition wherein second sidewall insulating films 64c in n-channel type transistor region 22 are thick. That is to say, p-type impurity region 34p of a high concentration, as the source region of MONOS element 71, and p-type impurity region 31p of a high concentration, as the drain region, are formed by injecting impurities into semiconductor substrate 1 using first sidewall insulating film 64a of a small width as a mask while n-type impurity regions 66, as the source region and the drain region of field-effect transistor 73, are formed by injecting impurities into semiconductor substrate 1 using second sidewall insulating film 64c of a great width as a mask.

In non-volatile semiconductor memory device 100 according to the third embodiment of the present invention formed in the above described manner, the width W2 of the region where first gate electrode 51 and p-type impurity region 31p of a high concentration, which forms the drain region, overlap can be secured and, therefore, the GIDL efficiency becomes great so that injection of electrons becomes easy. Furthermore, the generation of hot carriers in n-channel type transistor region 22, which is the periphery, can be prevented.

Fourth Embodiment

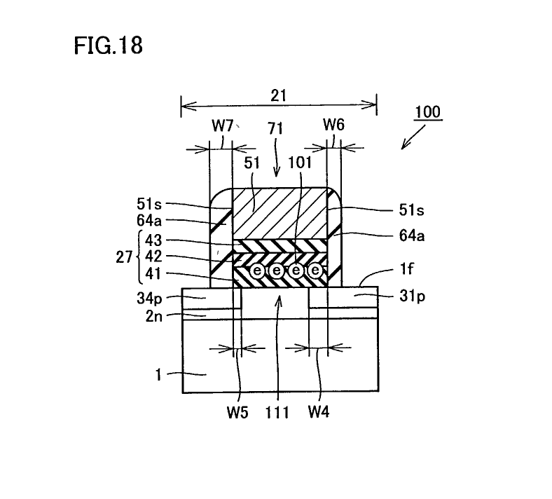

With reference to FIG. 18, a non-volatile semiconductor memory device 100 according to a fourth embodiment of the present invention has a memory cell region 21 formed in semiconductor substrate 1. An n-type well region 2n is formed in semiconductor substrate 1 in memory cell region 21. A MONOS element 71 is formed in n-type well region 2n.

MONOS element 71 has a pair of p-type impurity regions, 34p and 31p, of a high concentration as the source and drain regions formed at a distance from each other and a first gate electrode 51 formed above main surface 1f between these regions. P-type impurity regions 34p and 31p of a high concentration are formed within an n-type well region 2n. P-type impurity region 34p of a high concentration is the source region while p-type impurity region 31p of a high concentration is the drain region.

First gate insulating film 111 is formed on main surface 1f so as to be interposed between a pair of source and drain regions. First gate insulating film 111 is constituted by an ONO film 27, and ONO film 27 has a first silicon oxide film 41 formed on main surface 1f, a silicon nitride film 42 formed on first silicon oxide film 41 and a second silicon oxide film 43 formed on silicon nitride film 42.

First gate electrode 51 is formed on first gate insulating film 111 and first sidewall insulating films 64a are formed so as to make contact with sidewalls 51s of the first gate electrode.

Non-volatile semiconductor memory device 100 is provided with: semiconductor substrate 1 having main surface 1f; n-type well region 2n as an n-type semiconductor region formed on semiconductor substrate 1; and MONOS element 71 as a non-volatile semiconductor memory element formed in n-type well region 2n. MONOS element 71 includes: first gate insulating film 111, as a first insulating film formed on main surface 1f so as to be located on n-type well region 2n; a first gate electrode 51 provided on first gate insulating film 111; and a pair of p-type impurity regions of high concentration 34p and 31p, as source region and drain region, formed in n-type well region 2n and on both sides of first gate electrode 51, and constituted by the p-type impurity region.

First gate insulating film 11 includes: first silicon oxide film 41 formed on main surface 1f; silicon nitride film 42 formed on first silicon oxide film 41; and second silicon oxide film 43 formed on silicon nitride film 42. MONOS element 71, as a non-volatile semiconductor memory element, stores information by injecting electrons into first gate insulating film 111.

P-type impurity regions 34p and 31p of a high concentration have portions making contact with first silicon oxide film 41 and facing to first gate electrode 51. The width W4 of the portion of p-type impurity region 31p of a high concentration, which is the drain region, facing to first gate electrode 51 is greater than the width W5 of the portion of p-type impurity region 34p of a high concentration, which is the source region, facing to first gate electrode 51.

Non-volatile semiconductor memory device 100 is further provided with first sidewall insulating films 64a, as a pair of sidewall insulating films, formed on sidewalls 51s on each side of first gate electrode 51. The sidewall insulating film provided on the source region side has a relatively great width W7 while sidewall insulating film 64a provided on the drain region side has a relatively small width W6.

As for a manufacturing method for such a non-volatile semiconductor memory device 100, a resist mask that exposes p-type impurity region 31p of a high concentration, which is the drain region, is formed before the formation of p-type impurity regions 34p and 31p of a high concentration. Sidewall insulating films 64a are etched using this resist pattern as a mask, thereby the width of sidewall insulating film 64a on the drain region side is reduced. P-type impurity regions are implanted using sidewall insulating films 64a as a mask, thereby p-type impurity region 34p of a high concentration, as the source region, and p-type impurity region 31p of a high concentration, as the drain region, are formed. Thereby, the overlap region of p-type impurity region 31p of a high concentration and first gate electrode 51 can be expanded solely on the drain side wherein the generation of GIDL is desired. In contrast to this, the width W7 of sidewall insulating film 64a can be conventionally secured on the source side and, therefore, the channel length of the cell transistor is shortened only by the length of one side so that the short channel effect can be suppressed.

Fifth Embodiment

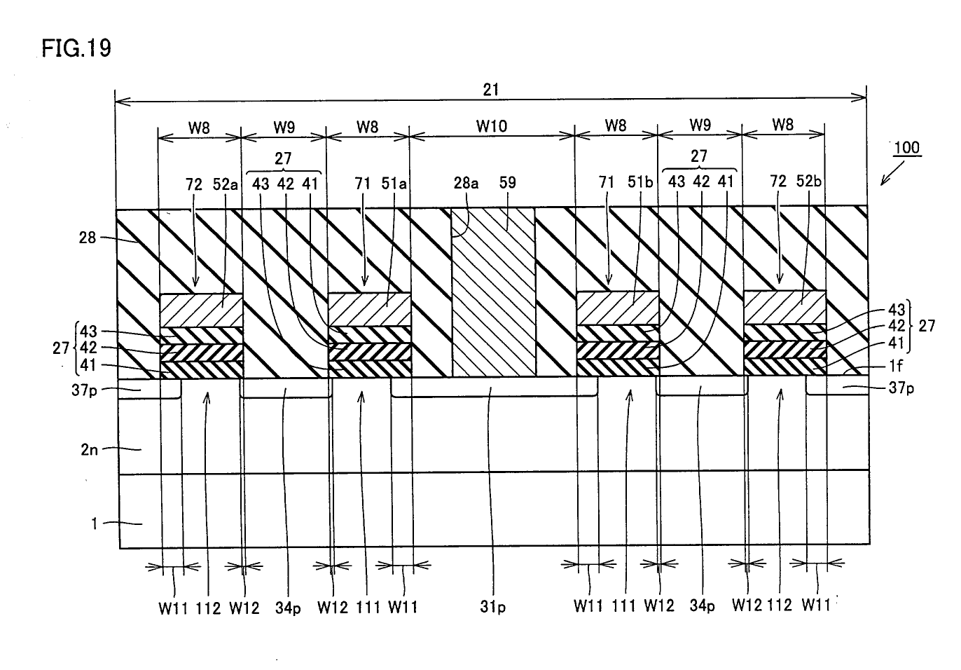

With reference to FIG. 19, an n-type well region 2n is formed in a semiconductor substrate 1 in a non-volatile semiconductor memory device according to a fifth embodiment of the present invention. MONOS elements 71 and 72 are formed in n-type well region 2n. MONOS elements 71 and 72 have p-type impurity regions 34p of a high concentration as the source regions and p-type impurity regions 31p and 37p of a high concentration as the drain regions.

In addition, MONOS elements 71 and 72 have first and second gate insulating films 111 and 112 formed between the source regions and the drain regions and gate electrodes 51a, 51b, 52a and 52b formed on these gate insulating films. First and second gate insulating films 111 and 112 are constituted by ONO films 27, and these ONO films 27 are formed by layering first silicon oxide films 41, silicon nitride films 42 and second silicon oxide films 43. Gate electrodes 51a and 52a are formed on first and second gate insulating films 111 and 112.

P-type impurity region 34p of a high concentration, as the source region, and p-type impurity region 31p of a high concentration, as the drain region have portions contacting first silicon oxide film 41 and facing gate electrode 51a, as the first gate electrode. The width of the portion of p-type impurity region 31p of a high concentration, as the drain region facing gate electrode 51a is greater than the width of the portion of p-type impurity region 34p of a high concentration, as the source region, facing gate electrode 51a, as the first gate electrode.

Non-volatile semiconductor memory device 100 is further provided with: a second gate electrode 52a formed on the p-type impurity region 34p side of a high concentration, as the source region, so as to be isolated from gate electrode 51a; and gate electrode 51b, as the third gate electrode, formed on the p-type impurity region 31p side of a high concentration, as the drain region, so as to be isolated from gate electrode 51a. The distance W10 between gate electrode 51a and gate electrode 51b is greater than the distance W9 between first gate electrode 51a and gate electrode 52a. The width W8 of each of the gate electrodes 51a and 52a and the width W9 between the gate electrodes in p-type impurity region 34p of a high concentration, as the source region, are approximately equal. In contrast to this, the distance W10 between the gate electrodes in p-type impurity region 31p of a high concentration, as the drain region, is approximately twice as W8.

Next, a manufacturing method for the non-volatile semiconductor memory device shown in FIG. 19 will be described. A diagonal injection of impurity ions is utilized in order to form the source regions and the drain regions shown in FIG. 19.

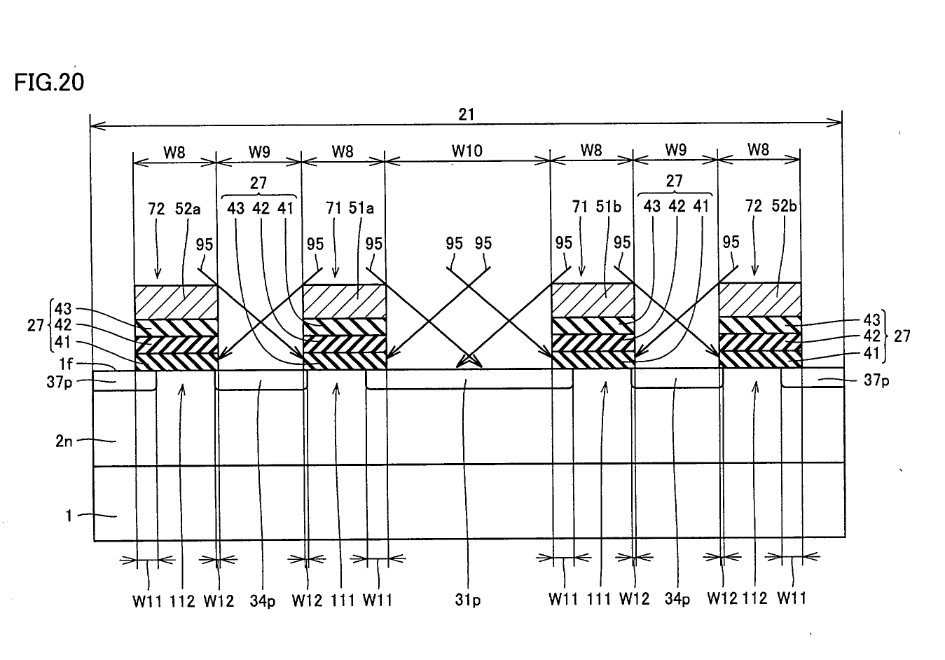

That is to say, as shown in FIG. 20, impurity ions are injected into semiconductor substrate 1 in the direction formed an acute angle relative to main surface 1f using the second and third gate electrodes as a mask, thereby p-type impurity regions 34p of a high concentration, as the source regions, and p-type impurity regions 31p of a high concentration, as the drain regions, are formed. At this time, the distances between the gate electrodes in p-type impurity regions 31p of a high concentration, as the drain regions, are great so that a sufficient amount of impurities is injected into the drain regions. Therefore, the width W11 of each of p-type impurity regions 31p of a high concentration facing gate electrodes 51a and 52a becomes relatively great.

In contrast to this, the widths between the gate electrodes in p-type impurity regions 34p of a high concentration, as the source regions, are narrow so that a sufficient amount of impurity ions is not injected. As a result, the width W12 of each of the portions of p-type impurity regions 34p of a high concentration, facing to gate electrodes 52a and 51a becomes relatively small.

The non-volatile semiconductor memory device according to the fifth embodiment of the present invention formed in such a manner, has the same effects as of non-volatile semiconductor memory device 100 according to the third embodiment.

According to the present invention, a GIDL-induced hot electron injection is used as an injection method of electrons in a p-channel type MONOS element, thereby the following effects are obtained. That is to say, the device can be manufactured at a low cost using a simplified process, in comparison with a flash memory. Miniaturization of the cell size becomes possible, in comparison with a conventional MONOS device. The device has excellent withstanding properties against rewriting, in comparison with an NROM (nitride read only memory).

The field-effect transistor includes a pair of source region and drain region formed in the p-type semiconductor regions and on both sides of the second gate electrode, and constituted by an n-type impurity region. The source region and the drain region of the non-volatile semiconductor memory element are formed by implanting impurities into the semiconductor substrate using the first sidewall insulating films as a mask while the source regions and the drain regions of the field-effect transistor are formed by implanting impurities into the semiconductor substrate using the second sidewall insulating films as a mask.

In this case, the source regions and the drain regions of the non-volatile semiconductor memory element and of the field-effect transistor are formed by injecting impurities into the semiconductor substrate using the first and second sidewall insulating films as a mask and, therefore, the distance between the first gate electrode and the source region in the non-volatile semiconductor memory element as well as the distance between the first gate electrode and the drain region in the non-volatile semiconductor memory element become relatively small while the distance between the second gate electrode and the source region in the field-effect transistor as well as the distance between the second gate electrode and the drain region in the field-effect transistor become relatively great. Therefore, the area of the portion where the first gate electrode and the drain region overlap becomes great in the non-volatile semiconductor memory device so that hot electrons can be generated in the portion of the drain facing the first gate electrode and these electrons can be injected into the first gate insulating film.

Impurity ions are injected into the semiconductor substrate using the second sidewall insulating films, having relatively great thicknesses, as a mask so that the source region and the drain region are formed in the n channel-type field-effect transistor and, therefore, the distance between the second gate electrode and the source region as well as the distance between the second gate electrode and the drain region become great. As a result, the distance between the source and drain regions can be secured so that the generation of hot carriers can be prevented.

The non-volatile semiconductor memory device is further provided with a pair of sidewall insulating films formed on the sidewalls on each side of the first gate electrode. The sidewall insulating film provided on the source region side has a relatively great width while the sidewall insulating film provided on the drain region side has a relatively small width. In this case, when the source region and the drain region are formed by implanting impurities into the silicon substrate using the sidewall insulating films as a mask, the drain region is formed in a portion close to the first gate electrode while the source region is formed in a portion far away from the first gate electrode. As a result, the width of the portion where the drain region and the first gate electrode face each other becomes great so that hot carriers are generated in the portion of the drain region facing the first gate electrode and these electrons can be injected into the first gate insulating film.

The non-volatile semiconductor memory device is further provided with a second gate electrode formed on the source region side so as to be isolated from the first gate electrode and with a third gate electrode formed on the drain region side so as to be isolated from the first gate electrode. The distance between the first gate electrode and the third gate electrode is greater than the distance between the first gate electrode and the second gate electrode.

The source region and the drain region are formed by implanting impurities into the semiconductor substrate in the direction forming an acute angle relative to the main surface using the second and third gate electrodes as a mask. The source region and the drain region have portions contacting the first silicon oxide film and facing the first gate electrode. The width of the portion of the drain region facing the first gate electrode is greater than the width of the portion of the source region facing the first gate electrode. As for the formation of such a source region and drain region, such a source region and drain region are formed by implanting impurity ions into the semiconductor substrate using the second and third gate electrodes as a mask. As a result, the source region and the drain region can be formed without specifically increasing the number of steps.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A non-volatile semiconductor memory device comprising:
a semiconductor substrate having a main surface;
an n-type semiconductor region formed in said semiconductor substrate;
a non-volatile semiconductor memory element formed in said n-type semiconductor region; and
a field-effect transistor formed in said n-type semiconductor region so as to be connected to said non-volatile semiconductor memory element, wherein
said non-volatile semiconductor memory element includes: a first gate insulating film formed on said main surface so as to be located on said n-type semiconductor region; a first gate electrode provided on said first gate insulating film; and a pair of source region and drain region formed in said n-type semiconductor region and on both sides of said first gate electrode, and constituted by a p-type impurity region, said first gate insulating film includes: a first silicon oxide film formed on said main surface; a silicon nitride film formed on said first silicon oxide film; and a second silicon oxide film formed on said silicon nitride film, and said non-volatile semiconductor memory element stores information by injecting an electron into said first gate insulating film, and
said field-effect transistor is formed on said main surface so as to be located on said n-type semiconductor region, and includes a second gate insulating film made of the same material as that of said first gate insulating film.

2. The non-volatile semiconductor memory device according to claim 1, wherein
said drain region has a portion making contact with said first silicon oxide film and facing to said first gate electrode, where a hot electron is generated in the portion facing to said first gate electrode of said drain region, thereby injecting an electron into said first gate insulating film.

3. The non-volatile semiconductor memory device according to claim 1, wherein
said first gate insulating film and said second gate insulating film directly make contact with each other.

4. The non-volatile semiconductor memory device according to claim 1, wherein
said first gate insulating film and said second gate insulating film are separated from each other.

5. A non-volatile semiconductor memory device comprising:
a semiconductor substrate having a main surface;
an n-type semiconductor region formed in said semiconductor substrate;
a non-volatile semiconductor memory element formed in said n-type semiconductor region;
a p-type semiconductor region formed in said semiconductor substrate; and
a field-effect transistor formed in said p-type semiconductor region, wherein
said non-volatile semiconductor memory element includes: a first gate insulating film formed on said main surface so as to be located on said n-type semiconductor region; a first gate electrode provided on said first gate insulating film; a first sidewall insulating film formed on a sidewall of said first gate electrode; and a pair of source region and drain region formed in said n-type semiconductor region and on both sides of said first gate electrode, and constituted by a p-type impurity region, said first gate insulating film includes: a first silicon oxide film formed on said main surface; a silicon nitride film formed on said first silicon oxide film; and a second silicon oxide film formed on said silicon nitride film, and said non-volatile semiconductor memory element stores information by injecting an electron into said first gate insulating film,
said field-effect transistor includes: a second gate electrode formed on said p-type semiconductor region so as to interpose a second gate insulating film therebetween; and a second sidewall insulating film formed on a sidewall of said second gate electrode, and
the width of said first sidewall insulating film in the channel length direction is smaller than the width of said second sidewall insulating film in the channel length direction.

6. The non-volatile semiconductor memory device according to claim 5, wherein
said field-effect transistor includes a pair of source region and drain region formed in said p-type semiconductor region and on both sides of said second gate electrode, and constituted by an n-type impurity region, said source region and said drain region of said non-volatile semiconductor memory element are formed by implanting an impurity into said semiconductor substrate using said first sidewall insulating film as a mask, and said source region and said drain region of said field-effect transistor are formed by implanting an impurity into said semiconductor substrate using said second sidewall insulating film as a mask.

7. A non-volatile semiconductor memory device comprising:
a semiconductor substrate having a main surface;
an n-type semiconductor region formed in said semiconductor substrate; and
an non-volatile semiconductor memory element formed in said n-type semiconductor region, wherein
said non-volatile semiconductor memory element includes: a first gate insulating film formed on said main surface so as to be located on said n-type semiconductor region; a first gate electrode provided on said first gate insulating film; and a pair of source region and drain region formed in said n-type semiconductor region and on both sides of said first gate electrode, and constituted by a p-type impurity region, said first gate insulating film includes: a first silicon oxide film formed on said main surface; a silicon nitride film formed on said first silicon oxide film; and a second silicon oxide film formed on said silicon nitride film, and said non-volatile semiconductor memory element stores information by injecting an electron into said first gate insulating film, and
said source region and said drain region have portions making contact with said first silicon oxide film and facing to said first gate electrode, and the width of the portion of said drain region facing to said first gate electrode is greater than the width of the portion of said source region facing to said first gate electrode.

8. The non-volatile semiconductor memory device according to claim 7, further comprising
a pair of sidewall insulating films formed on the both sidewalls of said first gate electrode, wherein
the width of the sidewall insulating film provided on said source region side has a relatively great width and said sidewall insulating film provided on said drain region side has a relatively small width.

9. The non-volatile semiconductor memory device according to claim 7, further comprising:
a second gate electrode formed on said source region side so as to be isolated from said first gate electrode; and
a third gate electrode formed on said drain region side so as to be isolated from said first gate electrode, wherein
the distance between said first gate electrode and said third gate electrode is greater than the distance between said first gate electrode and said second gate electrode.

10. The non-volatile semiconductor memory device according to claim 9, wherein
said source region and said drain region are formed by implanting an impurity into said semiconductor substrate in the direction forming an acute angle relative to said main surface using said second and third gate electrodes as a mask, said source region and said drain region have portions making contact with said first silicon oxide film and facing to said first gate electrode, and the width of the portion of said drain region facing to said first gate electrode is greater than the width of the portion of said source region facing to said first gate electrode.
